(19) United States
(12) Patent Application Publication
(10) Pub. No.: US 2024/0021542 A1
(43) Pub. Date: Jan. 18, 2024

(54) POWER SEMICONDUCTOR DEVICE AND POWER MODULE

(71) Applicant: Hitachi Energy Switzerland AG, Baden (CH)

(72) Inventors: Marco BELLINI, Zürich (CH); Lars KNOLL, Hägglingen (CH); Jürgen SCHUDERER, Zürich (CH); Oriol LOPEZ SANCHEZ, Saint-Légier-La Chiésaz (CH)

(21) Appl. No.: 18/035,496

(22) PCT Filed: Nov. 5, 2020
(86) PCT No.: PCT/EP2020/081141

§ 371 Date: May 4, 2023

(51) Int. Cl. H01L 23/00; H01L 21/56; H01L 23/31

(52) U.S. Cl. CPC H01L 23/564; H01L 21/561; H01L 23/3171; H01L 23/3192

(57) ABSTRACT

In at least one embodiment, the power semiconductor device (1) comprises
a semiconductor body (2), and
a protection layer (3) at the semiconductor body (2), wherein
the protection layer (3) comprises a material having a surface energy of at most 0.1 mJ/m2, and
the protection layer (3) comprises a geometric structuring (33) having a feature size (F) of at least 0.04 μm and of at most 0.1 mm, seen in top view of the protection layer (3).

A power semiconductor device is provided. A power module comprising such a power semiconductor device is also provided.

Document WO 2003/001612 A1 refers to a package having a recess where a semiconductor chip is contained, and a sealing member placed in the recess.

Document EP 1 018 158 A1 refers to a hydrophobic polymeric coating.

Document C. Zorn and N. Kaminski, “Acceleration of temperature humidity bias (THB) testing on IGBT modules by high bias levels”, 2015 IEEE 27th International Symposium on Power Semiconductor Devices & IC's (ISPSD), Hong Kong, 2015, pages 385 to 388, DOI: 10.1109/ISPSD.2015.7123470, refers to the effect of humidity on IGBT modules.

A problem to be solved is to provide a power semiconductor device that can be operated in a comparably humid environment.

This object is achieved, inter alia, by a power semiconductor device and by a power module as defined in the independent patent claims. Exemplary further developments constitute the subject matter of the dependent patent claims.

For example, the power semiconductor device comprises a protection layer with a geometric structuring so that the protection layer is ultra-hydrophobic. Hence, a continuous water film along a surface of the power semiconductor device between electrodes can be avoided so that electro-chemic degradation and damage to the power semiconductor device can be reduced or avoided.

In at least one embodiment, the power semiconductor device comprises a semiconductor body and a protection layer at the semiconductor body. The protection layer comprises a material having a surface energy of at most 0.1 mJ/m2, and the protection layer comprises a geometric structuring having a feature size of at least 0.04 μm and of at most 0.1 mm, seen in top view of the protection layer.

For example, the surface energy is determined through contact angle experiments wherein a contact angle meter may be used. The surface energy and/or the contact angle may be measured at room temperature, that is, at 300 K, and at standard pressure, that is, at 1013 hPa. Exemplarily, the surface energy and/or the contact angle are measured in air. For example, polytetrafluoroethylene, PTFE for short, has a surface energy of 19 mJ/m², glass has a surface energy of about 0.08 J/m², depending on the specific glass, and calcium carbonate has a surface energy of ²³ mJ/m². A material that may be used for the semiconductor body and having a high surface energy is, for example, silicon with a surface energy of 1.2 J/m².

When producing power semiconductor devices, several manufacturing steps and also operation environments may cause issues for the performance of the power semiconductor device. For example, dicing and soldering generate a number of particles that can stick to a passivation layer, which can be a diamond-like carbon layer, DLC layer for short, or a polyimide layer, PI for short. Such particles may be very difficult to remove as in case of, for example, hot soldering particles.

Such particles can reduce a blocking voltage of the power semiconductor device, may alter the correct functioning of an electrical termination and could affect the yield of fabrication. For example, in case of bipolar metal-oxide-semiconductor (BiMOS) devices thick and expensive polyimide layers can be used to reduce the impact of particles on electrical terminations.

Humidity is also a problem for power semiconductor devices and power modules. For example, by the formation of a closed water film, such as a monolayer electrolytic solution, linking a chip-metallization of an active area being the negative electrode, that means the cathode, and a channel stopper metallization being the positive electrode, which is the anode, a corrosion cell may build up. Increasing the relative humidity, RH for short, can cause the accumulation of additional monolayers of water, and, thus, can increase the conductivity of the adsorbed moisture film.

In semiconductor packaging, humidity is also to be concerned because water vapor condensation leads to corrosion.

By means of the power semiconductor device described here having the protection layer with the geometric structuring, a surface protection during manufacturing and operation of the power semiconductor device can be achieved. The geometric structuring together with the low-surface energy material of the protection layer can provide a surface which is ultra-hydrophobic.

On ultra-hydrophobic surfaces, water droplets roll back and forth at the slightest inclination while retaining their spherical shape, collecting and removing dirt particles without leaving any residue. This effect is generally known from the lotus leaf and is therefore also called Lotus Effect. The ultra-hydrophobicity of the lotus leaf is due to a special hierarchical surface profile of microscopic nubs with nanoscopic wax hairs.

Moreover, a method for manufacturing the protection layer for the power semiconductor device is provided. The method comprises applying the protection layer with the geometric structuring. The patterned protection layer may be ultra-hydrophobic. Additionally, the method may comprise method steps according to features of any of the embodiments which are described in the following.

Hence, one aspect of the power semiconductor device described herein is to provide a specially patterned surface in, on or at the coating or passivation layers of power semiconductor devices and modules. The surface comprises or consists of, for example, a fine patterned structure, which may be periodically structured or randomly structured, with a feature size in the range from, for example, 0.04 μm to 100 μm inclusive so that an ultra-hydrophobic surface results by means of the protection layer.

The power semiconductor device is, for example, a device selected from the following group: a metal-oxide-semiconductor field-effect transistor (MOSFET), a metal-insulator-semiconductor field-effect transistor (MISFET), an insulated-gate bipolar transistor (IGBT), a bipolar junction transistor (BJT), a junction gate field-effect transistor (JFET), a thyristor like a gate turn-off thyristor (GTO) or a gate commutated thyristor (GCT), a diode. For example, the semiconductor body may be based on SiC, Si, GaN or another wide bandgap material.

For example, the power semiconductor device is a transistor, such as a silicon insulated-gate bipolar transistor (Si IGBT) or a Silicon carbide metal-oxide-semiconductor field-effect transistor (SiC MOSFET). Silicon Carbide offers some benefits compared to silicon, which are, for example, higher efficiency, higher switching frequency and higher temperature of operation.

A MOSFET or MISFET is an active electronic component with may comprise at least three electric terminals, that means electrodes, which are a gate, a source and a drain. In some designs, an additional terminal, which is a bulk or a substrate, may be led to an exterior of the power semiconductor device and may be connected to a back of a chip that includes or that is the power semiconductor device. Since a voltage at the back of the chip generates additional electric fields that act on a channel of a transistor structure, changing the voltage at the back terminal may shift a threshold voltage of the MOSFET. However, in most cases the substrate is internally connected to the source.

The ultra-hydrophobic surface resulting from the protection layer enables simple and effective cleaning of the semiconductor body and particle removal with a water spray gun, for example. Furthermore, the protection layer protects the power semiconductor devices and power modules from environmental influences, such as humidity and corrosion, as demonstrated in solar cell applications and antenna coatings, for example. Since the ultra-hydrophobic protection layer can easily be cleaned with a water spray because the water will not wet the surface and will easily remove all contaminant particles created in the dicing and soldering steps. This can improve yield in a manufacturing process. Therefore, the power semiconductor device described herein allows to significantly reduce fabrication costs.

Furthermore, in several cases, the surface of the protection layer enables self-cleaning of, for example, a passivation layer and removal of particles due the dicing and soldering steps which are strong yield detractors. On self-cleaning surfaces water drops are able to move upon slopes with an angle of inclination of <10°. The water drops need not to slide but can roll, and they can pick up dirt when rolling.

In addition, the protection layer can provide a reduction of a thickness of polyimide layers which are applied in the power semiconductor devices, or also an omission of such layers is possible, which can reduce the cost of fabrication.

According to at least one embodiment, the power semiconductor device is configured for a current of at least 10 A or of at least 50 A. As an option, said current is at most 500 A. Alternatively or additionally, the power semiconductor device is configured for a voltage of at least 0.6 kV or of at least 1.2 kV. As an option, said voltage may be at most 6.5 kV.

According to at least one embodiment, the protection layer partially or completely covers a top side of the semiconductor body. The top side may be a main side of the semiconductor body, that is, a largest side. As an option, the top side is provided with one electric contact area or with a plurality of electric contact areas. The at least one electric contact area is configured to be electrically connected by means of, for example, welding or soldering. It is possible that the top side is completely covered by the protection layer together with the at least one electric contact area, wherein the at least one electric contact area may in part be covered by the protection layer.

Seen in top view of the top side, an edge length of the semiconductor body may be at least 1 mm and/or at most 2 cm. Hence, a distance between electric contact areas may be at least 0.5 mm and/or at most 1.5 cm.

According to at least one embodiment, a contact angle of the protection layer with clean water, at 300 K and 1013 hPa in air, is at least 150° or is at least 160° or is at least 170°. Hence, at least in an environment with normal pressure conditions and temperatures, such as normal room temperature and pressure, the protection layer can offer a surface that is ultra-hydrophobic. For example, clean water refers to deionized or distilled water.

According to at least one embodiment, the geometric structuring comprises a plurality of pillars. For example, a height of the pillars exceeds a diameter of the pillars by at least a factor of 30 or by at least a factor of 50 and/or by at most a factor of 300 or by at most a factor of 200.

According to at least one embodiment, the diameter of the pillars is at least 50 nm and/or at most 200 nm. If a cross-section of the pillars is not circular, then the diameter can be calculated as the square root of four times a cross-sectional area divided by π. For example, the cross-sectional area is circular or rectangular or hexagonal or square. The pillars may be of pyramidal, truncated pyramidal, prismatic or conical shape.

According to at least one embodiment, the geometric structuring comprises one grid or a plurality of grids. For example, the at least one grid is formed by walls. Seen in top view, the grid may be honeycombed or rectangular.

According to at least one embodiment, a height of the at least one grid exceeds a width of the walls by at least a factor of 5 or by at least a factor of 10 and/or by at most a factor of 200 or by at most a factor of 100 or by at most a factor of 50. Seen in cross-section, for example, the walls could be of rectangular, triangular, trapezoid or biconvex shape.

According to at least one embodiment, the protection layer comprises a base layer. For example, the base layer is a continuous uninterrupted layer without any voids or holes. This applies, for example, in the area of the pillars and/or of the at least one grid.

If there is a base layer and also pillars and/or the at least one grid, the base layer and the pillars and/or the at least one grid can be of the same material or can be of different materials. For example, the pillars and/or the at least one grid is/are produced by etching the base layer wherein the base layer can remain as a continuous layer extending across the whole protection layer.

Otherwise, the pillars and/or the at least one grid can be produced by completely etching through a first layer so that a second layer directly below the first layer may act as an etch stop layer.

According to at least one embodiment, the protection layer comprises a plurality of spacer bodies. The spacer bodies can be applied on the base layer. For example, the spacer bodies are small spheres of a material like silica. A diameter of the spacer bodies may be, for example, at least 50 nm or 0.5 μm and/or at most 0.1 mm or at most 10 μm.

According to at least one embodiment, the protection layer is directly applied on the semiconductor body. In this case, the protection layer can be electrically insulating. That is, the protection layer could be a passivation layer for the semiconductor body.

According to at least one embodiment, the protection layer is distant from the semiconductor body. Hence, the protection layer and the semiconductor body do not touch. For example, at least one electrically insulating passivation layer is located between the semiconductor body and the protection layer. In this case, the protection layer can also be electrically insulating, like the separate passivation layer, or the protection layer can also be conductive or semi-conductive.

According to at least one embodiment, the protection layer comprises or consists of at least one organic material. For example, the protection layer is of PTFE or of PI.

According to at least one embodiment, the protection layer comprises or consists of at least one inorganic material. For example, the protection layer is of SiO₂ or of a glass.

According to at least one embodiment, the protection layer is adapted to be provided as an additional layer on the passivation layer of a field oxide (FOX) layer, or the protection layer is adapted to be provided as an additional layer on, for example, a polyimide layer. Polymer hydrogen silsesquioxane (HSQ) solution in methyl isobutyl ketone (MIBK) commercially known as FOX is an alternative material to silicon dioxide obtained by chemical deposition. This allows that other process steps for manufacturing the component do not have to be changed despite having the additional protection layer. Hence, only an additional process step is necessary.

According to at least one embodiment, the passivation layer is a passivation oxide layer, wherein the protection layer is provided by using etching or coating. Etching or coating are well-established processes in which the process conditions can be set reproducibly. Furthermore, by coating the protection layer can be applied as an additional layer. With etching an already existing functional layer of the semiconductor device, like the base layer, said layer can be provided with the hydrophobic properties.

According to at least one embodiment, the protection layer is provided on the polyimide layer by using etching or coating with micro elements, such as with silica spheres, as the spacer bodies. Silica microspheres and nanospheres can be ceramic spherical beads with tight particle size distributions. They can be used as a dry powder. Such spacer bodies are chemically-stable, inert, and safe materials.

Untreated silica spheres are usually hydrophilic and negatively charged. Further advantage of using such silica spheres is that their parameters are not fixed, and might vary depending on the properties of the system the spheres are incorporated into. For example, silica spheres can be manufactured using proprietary technologies which allow the essential properties of amorphous silica to be maintained while simultaneously achieving controlled spherical shape and uniform particle size.

If spacer bodies are used in the protection layer, it is possible that bare spacer bodies are used. Otherwise, the spacer bodies can be provided with at least one coating to adjust surface properties of the spacer particles. Such a coating can be of organic molecules or of Si-containing molecules such as silanes.

According to at least one embodiment, the protection layer is provided in the polyimide layer or in a diamond-like carbon (DLC) layer. The protection layer provides a reduction of a thickness of polyimide layers which are applied in power semiconductor devices, or also an omission of such layers, which reduces the cost of fabrication.

Hence, the protection layer can be made of PI or DLC or can be applied to a layer made of PI or DLC. PIs include polysuccinimide (PSI), polybismaleimide (PBMI), polyimide sulfone (PISO) and polymethacrylimide (PMI). Polyimide dissolved in dimethylformamid (DMF), dimethylacetamid (DMAc) or N-methyl-2-pyrrolidon (NMP) solvents may be suitable for use as a coating agent. DLC is an amorphous carbon material that provides the properties of diamond.

According to at least one embodiment, the geometric structuring is of regular fashion. For example, the geometric structuring is applied in a regular hexagonal, trigonal, square or rectangular pattern. For example, a periodicity of the geometric structuring is constant with a tolerance of at most 10% or of at most 20% across the whole protection layer.

According to at least one embodiment, the geometric structuring is of irregular fashion. Hence, the geometric structuring may be applied in a random manner, for example, by means of strewing the spacer bodies onto the base layer.

According to at least one embodiment, the feature size is at least 0.5 μm and at most 3 μm or at least 0.5 μm and at most 2 μm. By means of such a feature size, structures of the protection layer are smaller than drops of water under normal conditions. Thus, such a structure contributes to an ultra-hydrophobic surface.

A power module is additionally provided. The power module may comprise a power semiconductor device as indicated in connection with at least one of the above-stated embodiments. Features of the power semiconductor device are therefore also disclosed for the power module and vice versa.

In at least one embodiment, the power module comprises one or a plurality of the power semiconductor devices, a base plate on which the at least one power semiconductor device is mounted, and an encapsulation layer in direct contact with the protection layer of the at least one power semiconductor device.

For example, the base plate is a leadframe, a circuit board or a heat sink. The base plate may comprise an electric wiring to electrically connect the at least one power semiconductor device.

For example, the encapsulation layer forms a hull around the at least one power semiconductor device to protect the at least one power semiconductor device against environmental influences like humidity. The encapsulation layer may be hydrophobic. For example, the encapsulation layer is an epoxy or a polysiloxane.

According to at least one embodiment, the encapsulation layer is interrupted by at least one crack. Because of the crack or the cracks, the protection layer is in places free of the encapsulation layer. Hence, at the at least one crack humidity may reach the protection layer. Thus, without the protection layer there may result water films which may lead to increased corrosion of metallic parts of the power semiconductor devices

The power semiconductor device is, for example, for a power module in a vehicle to convert direct current from a battery to alternating current for an electric motor, for example, in hybrid vehicles or plug-in electric vehicles.

A manufacturing method is additionally provided. The method may be used to produce a power semiconductor device as indicated in connection with at least one of the above-stated embodiments. Features of the power semiconductor device and of the power module are therefore also disclosed for the method and vice versa.

In at least one embodiment, the method comprises at least one of dicing and soldering. Dicing is the process by which dies are separated from a wafer of semiconductor material following the processing of the wafer. The dicing process can involve scribing and breaking, mechanical sawing or laser cutting. The process steps according to the method can be carried out with considerably reduced or no damage to the performance of the power semiconductor devices. The production costs can be reduced considerably, since fewer pieces have to be sorted out in a final test. Also, very easy cleaning of the power semiconductor devices is possible due to the effects of the protection layer.

According to at least one embodiment, the protection layer is applied at least one of before dicing or before soldering or after completion of all process steps carried out on a wafer. “After completion of all process steps carried out on a waver” means, for example, that any process steps being carried out on the wafer to produce the power semiconductor device have been completed. Further steps, such as cutting out of the wafer, may be carried out after having provided the protection layer.

A power semiconductor device and a power described herein are explained in greater detail below by way of exemplary embodiments with reference to the drawings. Elements which are the same in the individual figures are indicated with the same reference numerals. The relationships between the elements are not shown to scale, however, but rather individual elements may be shown exaggeratedly large to assist in understanding.

In the figures:

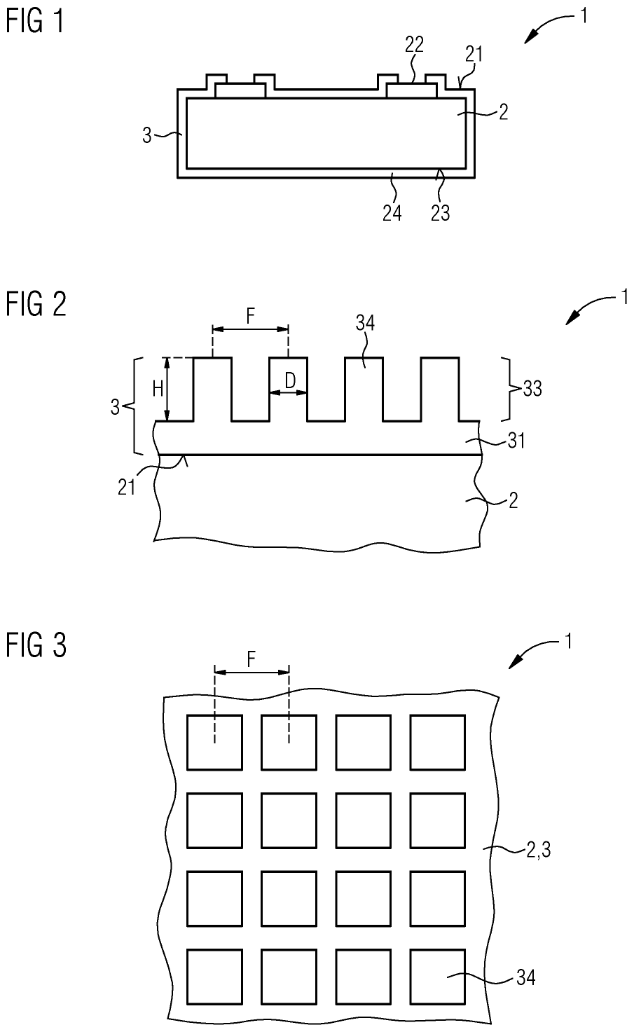

FIGS. 1 and 2 are schematic sectional views of exemplary embodiments of power semiconductor devices described herein,

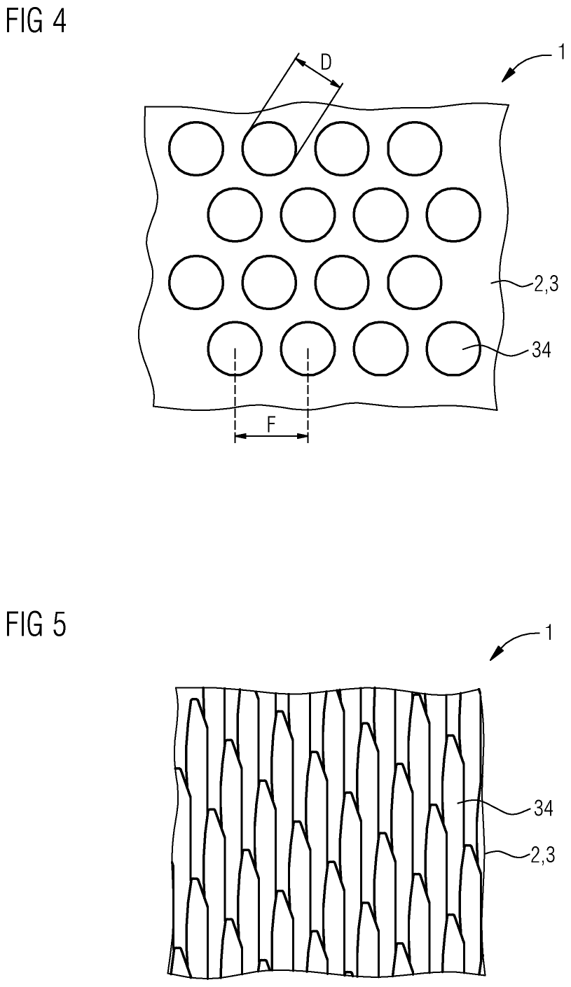

FIGS. 3 and 4 are schematic top views of exemplary embodiments of power semiconductor devices described herein,

FIG. 5 is a schematic perspective view of an exemplary embodiment of a power semiconductor device described herein,

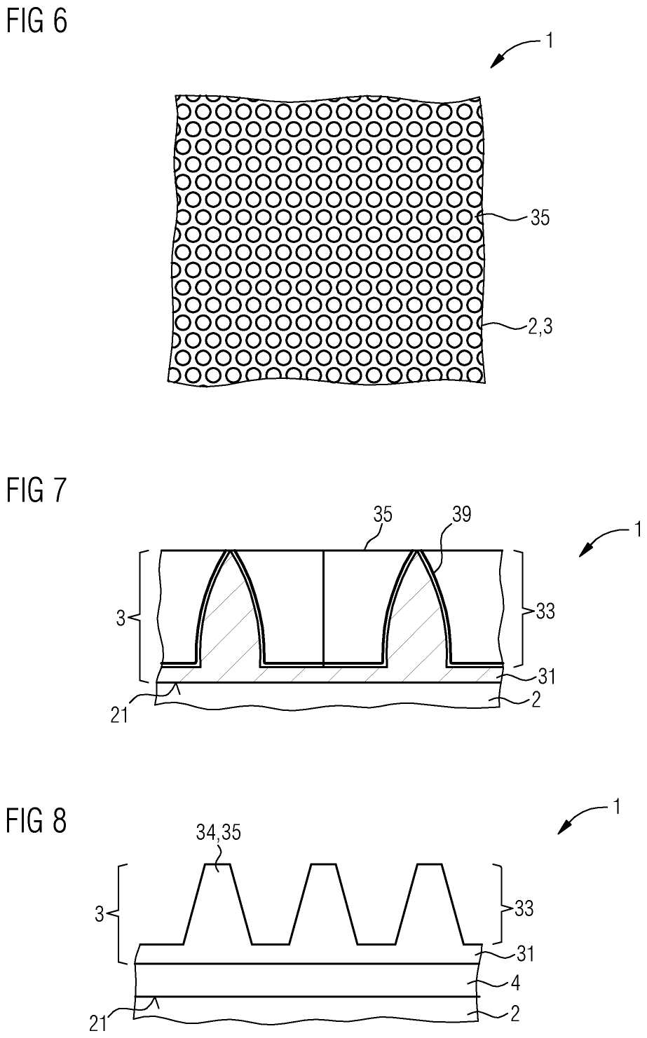

FIG. 6 is a schematic top view of an exemplary embodiment of a power semiconductor device described herein,

FIGS. 7 to 11 are schematic sectional views of exemplary embodiments of power semiconductor devices described herein, and

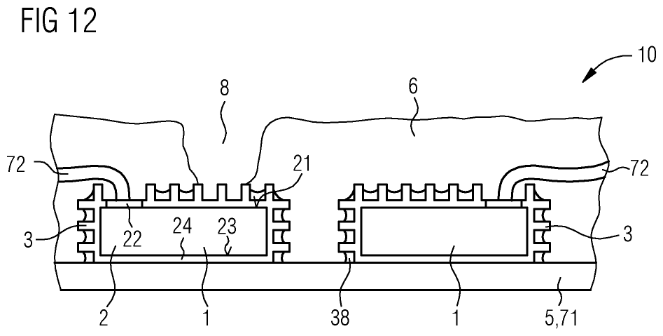

FIG. 12 is a schematic sectional view of an exemplary embodiment of a power module comprising power semiconductor devices described herein.

FIG. 1 shows an exemplary embodiment of a power semiconductor device 1. The power semiconductor device 1 comprises a semiconductor body 2 which is based, for example, on SiC. At a top side 21 of the semiconductor body 2, there are two electric contact areas 22, but it is also possible that there is only one electric contact area 22 at the top side 21.

Further, as an option, there can be an electric contact area 24 at a back side 23 of the semiconductor body 2, the back side 23 is on a side of the semiconductor body 2 remote from the top side 21. For example, the electric contact area 24 may completely cover the back side 23.

Moreover, the power semiconductor device 1 comprises a protection layer 3. The protection layer 3 is of a material having a low surface energy and has a structured surface, not illustrated in FIG. 1, so that the protection layer 3 can have ultra-hydrophobic properties. Together with the electric contact areas 22, the protection layer 3 may completely cover the top side 21, wherein the protection layer 3 may partially cover the electric contact areas 22 or may terminate flush with the electric contact areas 22. As an option, the protection layer 3 may also cover side faces of the semiconductor body 2 while the back side 23 may be free of the protection layer 3.

In FIGS. 2 to 11, exemplary embodiments of the protection layer 3 are illustrated. All these exemplary embodiments of the protection layer 3 can be used in the power semiconductor device 1 described herein, individually or in any combination.

According to FIGS. 2 and 3, the protection layer 3 comprises pillars 34 and a base layer 31. All the pillars 34 start at the base layer 31 and point away from the semiconductor body 2. By means of the pillars 34, a geometric structuring 33 is realized.

For example, a feature size F of the geometric structuring 33, seen in top view of the top side 21, is at least 0.04 μm and at most 0.1 mm, for example, between 0.5 μm and 3 μm inclusive. Moreover, the protection layer 3 is of a material having a low surface energy. Hence, the protection layer 3 can provide a patterned surface that it is ultra-hydrophobic.

For example, the protection layer 3 is of PI, PTFE, DLC or SiO₂. Thus, the ultra-hydrophobic surface can be realized by making a rough surface from a low surface energy material, for example, by stretching a PTFE film.

For example, a diameter D of the pillars 34 is at least 50 nm and at most 200 nm. Additionally or alternatively, a height H of the geometric structuring 33 is between 3 μm and 15 μm inclusive, keeping a ratio of the height H and the diameter D in a range from, for example, 50 to 200 inclusive.

Thus, the ultra-hydrophobic properties are maintained as the wetting of the surface may start with droplet nucleation in a Cassie-Baxter state and growth at tops of the pillars 34 remote from the semiconductor body 2. An exemplary feature size F, that means, a periodicity of the geometric structuring 33, is smaller than a typical water droplet in high humidity environments. Alternatively or additionally, a spacing between the pillars 34 or a width of trenches between the pillars 34 may be at most 3 μm or at most 5 μm. For example, said spacing is in the range from 0.04 μm to 100 μm inclusive. For example, said spacing is between 0.5 μm and 2 μm inclusive.

The pillars 34 may be arranged in a hexagonal pattern. Alternatively or additionally, the pillars 34 can have a circular cross-section, seen in top view.

See FIG. 4, it is also possible that the pillars 34 are of cuboid shape having square base areas. In this case, the pillars 34 may be arranged in a square pattern.

In FIGS. 3 and 4, the geometric structuring 33 is provided in a regular manner. Alternatively, the geometric structuring 33 can also be applied in an irregular, random manner.

Otherwise, the same as to FIG. 1 also applies to FIGS. 2 to 4.

According to FIG. 5, the geometric structuring 33 is also formed by pillars 34. In this case, the pillars 34 are of cylindric fashion and taper towards tops so that the pillars 34 have point-like tips.

Otherwise, the same as to FIGS. 1 to 4 also applies to FIG. 5.

In FIGS. 6 and 7, the geometric structuring 33 is not formed by pillars 34, but by a grid 35. Hence, the grid 35 is formed by walls so that, for example, a hexagonal pattern is formed. Alternatively, the walls of the grid 35 may also form a trigonal or square pattern, compare also FIG. 4. In other words, the grid 35 may be regarded as a negative of the pattern of pillars 34 illustrated in FIGS. 2 to 4.

As can be seen from FIG. 7, the walls may taper in a direction away from the semiconductor body 2 so that the walls are of biconvex shape, seen in cross-section perpendicular with the top side 21. Alternatively, the walls may have, for example, a rectangular, dome-like, trapezoid or trigonal shape, seen in cross-section.

For example, the walls of the grid 35 start from the common base layer 31 applied on the top side 21.

As an option, there may be a thin coating 39 on the geometric structuring 33. For example, a thickness of the coating 39 is at least one monolayer or at least three monolayers and/or is at most 20 nm or at most 10 nm. The coating 39 may be, for example, of a fluorinated alkene or alkyl or of a silane or siloxane. By means of such a coating 39, the surface properties of the geometric structuring 33 may be adjusted. Such a coating could also be present in all other exemplary embodiments.

The protection layer 3 of FIGS. 1 to 7 is applied directly on the semiconductor body 2. Such a protection layer 3 may be formed by coating or etching. For example, such a protection layer 3 is made of an oxide like silicon dioxide or of a nitride like aluminum nitride. However, in all these exemplary embodiments as an option there can be at least one passivation layer 4 between the semiconductor body 2 and the protection layer 3, see FIG. 8. For example, such a passivation layer 4 is made of an oxide like silicon dioxide or of a nitride like aluminum nitride. There can be more than one passivation layer 4. For example, a thickness of the passivation layer 4 is at least 20 nm and/or at most 0.2 μm.

If there is at least one passivation layer 4, the protection layer 3 may be of an organic material like PI or PTFE.

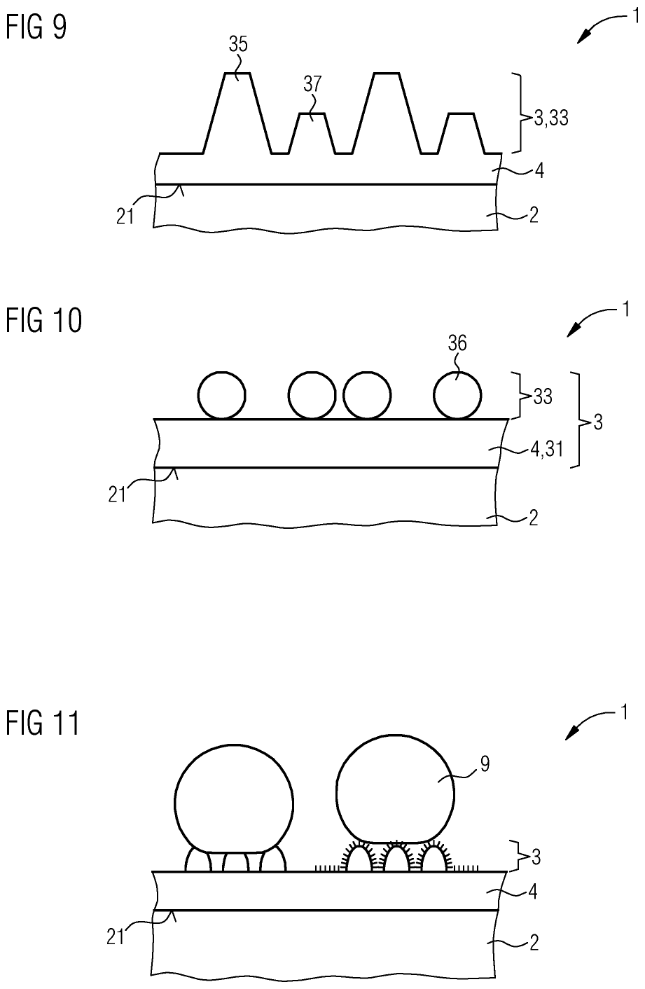

As illustrated in FIG. 8, as an option the protection layer 3 can comprise the continuous base layer 31 from which the geometric structuring 33 starts. Otherwise, see FIG. 9, there does not need to be a base layer 31 so that the geometric structuring 33 may start directly at the passivation layer 4. These two possibilities concerning the base layer 31 illustrated in FIGS. 8 and 9 can be realized in all other exemplary embodiments.

In FIG. 8 it is also shown that the pillars 34, or the grid 35, can be of trapezoid shape when seen in cross-section. Thus, the pillars 34 and/or the grid 35 may become narrower in a direction away from the semiconductor body 2. Such pillars 34 and/or such a grid 35 can be present in all other exemplary embodiments, too.

Further, see FIG. 9, it is possible that there is a further structuring 37 having a smaller height than the geometric structuring 33. Such a further structuring 37 may result from an etching process in combination with different crystallographic planes in a material for the protection layer 3. Such a further structuring 37 can be present in all other exemplary embodiments, too, but in each case there can be only the geometric structuring 33.

Otherwise, the same as to FIGS. 1 to 8 also applies to FIGS. 8 and 9.

According to FIG. 10, the geometric structuring 33 is realized by spacer bodies 36 arranged on the common base layer 31 or on the passivation layer 4. In this case, the base layer 31 and the passivation layer 4 may indeed be the same layer when the base layer 31 is of an electrically insulating material.

For example, a diameter of the spacer bodies 36 is at least 50 nm and/or at most 1 μm. The spacer bodies 36 can be of spherical shape, but other shapes like pillars are also possible. The spacer bodies 36 may be distributed in an irregular, random manner, but may also be distributed in a regular manner, for example, by means of structuring the base layer 31 and/or the passivation layer 4 or by means of self-alignment.

For example, the spacer bodies 36 are of an inorganic material like silica.

Such spacer bodies 36 can also be used in the geometric structuring 33 of all other exemplary embodiments. Hence, otherwise the same as to FIGS. 1 to 9 also applies to FIG. 10. In this context it is noted that the pillars 34, the at least one grid 35 and/or the spacer bodies 36 may be combined in one protection layer 3.

In FIG. 11, the effect of the geometric structuring 33 is illustrated. Thus, drops of water 9 have a large contact angle with the protection layer 3.

It is noted that the geometric structuring 33 can be of hierarchical design, see FIG. 11, right side. That is, there can be a smaller geometric structuring 33 applied on a larger geometric structuring 33. The same applies to all other exemplary embodiments.

In FIG. 12, a power module 10 is illustrated. The power module 10 comprises, for example, two of the power semiconductor devices 1 of at least one of FIGS. 1 to 11. For better understanding, the geometric structuring is drawn exaggeratedly large.

The power semiconductor devices 1 may be arranged on a base plate 5 that can comprise a first electric wiring 71 to electrically contact the power semiconductor devices 1. Moreover, there can be a second electric wiring 72, for example, bond wires, to contact the power semiconductor devices 1.

Moreover, there is an encapsulation layer 6 like a silicone resin or an epoxy. Intentionally, the encapsulation layer 6 encapsulates the power semiconductor devices 1. However, during operation of the power module 10 cracks 8 may arise so that water may reach the power semiconductor devices 1. By means of the then freed protection layer 3 it can be avoided that a continuous water film can connect the electric contact area 22, 24, for example, so that the risk of degradation or failure of the power module 10 can be reduced.

Hence, the ultra-hydrophobic protection layer 3 may be patterned either directly on top of the optional passivation layer 4, for example, in a field oxide (FOX) layer comprising SiO₂ or in a polyimide or DLC layer. In this case, a comparably thin polyimide layer can be used as particles from dicing and soldering can easily be removed with a water spray gun.

Then after the module assembly, the encapsulation layer 6 will have improved adhesion and mechanical anchoring by wetting and completely or partially filling up the ultra-hydrophobic geometric structuring 33 as, for example, silicone sticks well to SiO₂.

A further possibility to create the protection layer 3 is modifying a rough surface with a material of low surface energy. There are many ways to make rough surfaces, including those mentioned above such as mechanical stretching, laser treatment, plasma treatment, or chemical etching, lithography, sol-gel processing and solution casting, layer-by-layer and colloidal assembling, electrical/chemical reaction and deposition, electrospinning and chemical vapor deposition. There are also several methods than can be used to modify the chemistry of a surface to produce the protection layer 3. For example, covalent bonds can be formed between gold and alkyl thiols. Silanes can be used to decrease the surface energy.

Possible techniques to make rough surfaces and subsequent modifications of the surface chemistry are etching and lithography and sol-gel processing, for example, colloidal silica particles, and electrochemical reaction and deposition.

The invention described here is not restricted by the description given with reference to the exemplary embodiments. Rather, the invention encompasses any novel feature and any combination of features, including in particular any combination of features in the claims, even if this feature or this combination is not itself explicitly indicated in the claims or exemplary embodiments.

### LIST OF REFERENCE SIGNS

1 power semiconductor device
2 semiconductor body
21 top side
22 electric contact area at the top side
23 back side
24 electric contact area at the back side
3 protection layer
31 base layer
33 geometric structuring
34 pillar
35 grid
36 spacer body
37 further structuring
38 empty space
39 coating
4 passivation layer
5 base plate
6 encapsulation layer
71 first electric wiring
72 second electric wiring
8 crack
9 water
10 power module
D diameter
F feature size
H height
W width

1. A power semiconductor device comprising:
a semiconductor body, and
a protection layer at the semiconductor body,
wherein
the protection layer comprises a material having a surface energy of at most 0.1 mJ/m2, and
the protection layer comprises a geometric structuring having a feature size of at least 0.04 μm and of at most 0.1 mm, seen in top view of the protection layer, and
the protection layer comprises as base layer, and wherein a plurality of spacer bodies is applied on the base layer.

2. The power semiconductor device according to claim 1, wherein at least one of
the protection layer covers a top side of the semiconductor body that is a main side thereof, the top side is provided with at least one electric contact area, and
a contact angle of the protection layer with clean water, at 300 K and 1013 hPa in air, is at least 150°.

3. The power semiconductor device according to claim 1, wherein the geometric structuring comprises a plurality of pillars, and wherein a height of the pillars exceeds a diameter of the pillars by at least a factor of 30 and by at most a factor of 300.

4. The power semiconductor device according to claim 1, wherein the geometric structuring comprises at least one grid formed by walls, a height of the at least one grid exceeds a width of the walls by at least a factor of 5 and by at most a factor of 200.

5. (canceled)

6. The power semiconductor device according to claim 1, wherein at least one of
the protection layer is directly applied on the semiconductor body, and
the protection layer is electrically insulating.

7. The power semiconductor device according to claim 1, wherein the protection layer is distant from the semiconductor body, and wherein at least one electrically insulating and continuous passivation layer is located between the semiconductor body and the protection layer.

8. The power semiconductor device according to claim 1, wherein the protection layer comprises at least one organic material.

9. The power semiconductor device according to claim 1, wherein the protection layer comprises at least one inorganic material.

10. The power semiconductor device according to claim 1, wherein the geometric structuring is of regular fashion.

11. The power semiconductor device according to claim 1, wherein the geometric structuring is of irregular fashion.

12. The power semiconductor device according to claim 1, wherein the feature size is at least 0.5 μm and at most 3 μm.

13. The power semiconductor device according to claim 1, wherein the power semiconductor device is a transistor configured for a current of at least 10 A and for a voltage of at least 0.6 kV.

14. The power semiconductor device according to claim 1, wherein the power semiconductor device is part of a power module comprising
a base plate on which the power semiconductor device is mounted, and
an encapsulation layer in direct contact with the protection layer.

15. (canceled)

16. A method for producing a power module comprising a base plate on which a power semiconductor device is mounted, and an encapsulation layer in direct contact with a protection layer of the power semiconductor device, the power semiconductor device comprising a semiconductor body, and the protection layer at the semiconductor body, wherein the protection layer comprises a material having a surface energy of at most 0.1 mJ/m2, and the protection layer comprises a geometric structuring having a feature size of at least 0.04 μm and of at most 0.1 mm, seen in top view of the protection layer, and the protection layer comprises a base layer, and wherein a plurality of spacer bodies is applied on the base layer, wherein the method comprises:
providing the at least one semiconductor body;
applying the protection layer on the at least one semiconductor body;
arranging the at least one power semiconductor device on the base plate that comprises a first electric wiring to electrically contact the at least one power semiconductor device; and
encapsulating the at least one power semiconductor device with the encapsulation layer which forms a hull around the at least one power semiconductor device to protect the at least one power semiconductor device against environmental influences, the encapsulation layer is of a hydrophobic material.
